(19) United States
(12) Patent Application Publication
(10) Pub. No.: US 2025/0374704 A1
(43) Pub. Date: Dec. 4, 2025

(54) INTERCONNECT SUBSTRATE AND METHOD OF MAKING THE SAME

(71) Applicant: SHINKO ELECTRIC INDUSTRIES CO., LTD., Nagano (JP)

(72) Inventors: Yuna KAMIOKA, Nagano (JP); Tomoyuki SHIMODAIRA, Nagano (JP); Kotaro KODANI, Nagano (JP)

(21) Appl. No.: 19/219,007

(22) Filed: May 27, 2025

(30) Foreign Application Priority Data
May 30, 2024 (JP) 2024-088360

(51) Int. Cl. H10F 55/00; H01L 23/15; H01L 23/498

(52) U.S. Cl. CPC H10F 55/18; H01L 23/15; H01L 23/498; H01L 23/49827

(57) ABSTRACT

An interconnect substrate includes a core layer that is translucent, a first photoelectric conversion member disposed on a first surface of the core layer, a first interconnect layer electrically connected to the first photoelectric conversion member, a second photoelectric conversion member disposed on a second surface of the core layer that is opposite the first surface, and a second interconnect layer electrically connected to the second photoelectric conversion member, wherein the first photoelectric conversion member and the second photoelectric conversion member are arranged at such positions as to exchange optical signals with each other through the core layer.

### CROSS-REFERENCE TO RELATED APPLICATIONS

The present application is based on and claims priority to Japanese Patent Application No. 2024-088360 filed on May 30, 2024, with the Japanese Patent Office, the entire contents of which are incorporated herein by reference.

### FIELD

The disclosures herein relate to interconnect substrates and methods of making an interconnect substrate.

### BACKGROUND

As known in the art, an interconnect substrate may have through-holes formed in a core layer substrate. In such an interconnect substrate, the interconnect layers each formed on a respective side of the core layer are electrically connected via through-interconnects arranged in the through-holes. An increase in the number of through-holes may reduce the strength of the core layer.

There may be a need to provide an interconnect substrate capable of suppressing a decrease in the strength of the core layer.

### Related Art Documents

### Patent Documents

[Patent Document 1] Japanese Patent Laid-Open Publication No. 2020-009813

### SUMMARY

According to an aspect of the embodiment, an interconnect substrate includes a core layer that is translucent, a first photoelectric conversion member disposed on a first surface of the core layer, a first interconnect layer electrically connected to the first photoelectric conversion member, a second photoelectric conversion member disposed on a second surface of the core layer that is opposite the first surface, and a second interconnect layer electrically connected to the second photoelectric conversion member, wherein the first photoelectric conversion member and the second photoelectric conversion member are arranged at such positions as to exchange optical signals with each other through the core layer.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view illustrating an example of an interconnect substrate according to a first embodiment;

FIGS. 2A through 2D are drawings illustrating an example of a manufacturing process of the interconnect substrate according to the first embodiment;

FIGS. 3A through 3C are drawings illustrating the example of the manufacturing process of the interconnect substrate according to the first embodiment;

FIGS. 4A through 4C are drawings illustrating the example of the manufacturing process of the interconnect substrate according to the first embodiment;

FIGS. 5A and 5B are drawings illustrating another example of a manufacturing process of an interconnect substrate according to the first embodiment; and

FIG. 6 is a cross-sectional view illustrating an example of an interconnect substrate according to a variation of the first embodiment.

### DESCRIPTION OF EMBODIMENTS

In the following, an embodiment of the invention will be described with reference to the accompanying drawings. In these drawings, the same components are denoted by the same reference numerals, and duplicate descriptions may be omitted.

### First Embodiment

### Structure of Interconnect Substrate

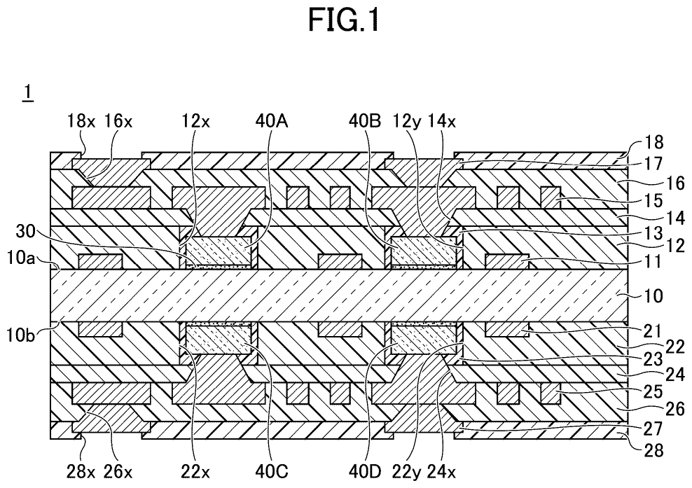

FIG. 1 is a cross-sectional view illustrating an example of an interconnect substrate according to a first embodiment. Referring to FIG. 1, an interconnect substrate 1 is configured such that interconnect layers and insulating layers are laminated on both sides of a core layer 10.

Specifically, the interconnect substrate 1 includes an interconnect layer 11, an insulating layer 12, an insulating layer 13, an insulating layer 14, an interconnect layer 15, an insulating layer 16, an interconnect layer 17, and a solder resist layer 18 successively laminated on the first surface 10a of the core layer 10. Further, an interconnect layer 21, an insulating layer 22, an insulating layer 23, an insulating layer 24, an interconnect layer 25, an insulating layer 26, an interconnect layer 27, and a solder resist layer 28 are successively laminated on the second surface 10b of the core layer 10.

In the first embodiment, for convenience, the solder resist layer 18 side of the interconnect substrate 1 is referred to as the upper side of the first side, and the solder resist layer 28 side is referred to as the lower side or the second side. In addition, the surface of a component oriented in the same direction as the solder resist layer 18 side is referred to as the first surface or the upper surface, and the surface of a component oriented in the same direction as the solder resist layer 28 side is referred to as the second surface or the lower surface. However, the interconnect substrate 1 may be positioned upside down when used, or may be arranged at any angle. The plan view refers to the view of an object as seen from the direction normal to the first surface 10a of the core layer 10, and the planar shape of an object refers to the shape of the object as seen from the direction normal to the first surface 10a of the core layer 10.

The core layer 10 is translucent, defined by having a transmittance of 80% or more in the wavelengths of the light emitted by the photoelectric conversion member, which will be described later. The core layer 10 may be made of, for example, glass. In this case, any kind of glass may be used, but for example, alkali-free glass, quartz glass, borosilicate glass, or the like may be used. The core layer 10 may alternatively be made of translucent sapphire. The core layer 10 may alternatively be made of translucent resin. The thickness of the core layer 10 is, for example, about 100 to 1000 μm.

The interconnect layer 11 is disposed on the first surface 10a of the core layer 10. The interconnect layer 11 is patterned in a predetermined planar shape. The material of the interconnect layer 11 may be, for example, copper (Cu) or the like. The thickness of the interconnect layer 11 is, for example, about 10 to 40 μm. The interconnect layer 11 is a representative example of the third interconnect layer of the present invention.

The insulating layer 12 is formed on the first surface 10a of the core layer 10 so as to cover the interconnect layer 11. The material of the insulating layer 12 may be, for example, a non-photosensitive thermosetting resin mainly composed of an epoxy-based resin or the like. A photosensitive resin may alternatively be used as the material of the insulating layer thickness of the insulating layer 12 is, for example, about 25 to 40 μm. The insulating layer 12 may contain a filler such as silica (SiO₂). The insulating layer 12 has openings 12x and 12y. The first surface 10a of the core layer 10 is situated at the bottoms of the openings 12x and 12y.

A photoelectric conversion member 40A is disposed on the first surface 10a of the core layer 10 situated within the opening 12x via a translucent optical adhesive 30. A photoelectric conversion member 40B is disposed on the first surface 10a of the core layer 10 situated within the opening 12y via a translucent optical adhesive 30. The thicknesses of the photoelectric conversion member 40A and the photoelectric conversion member 40B are preferably smaller than the thickness of the insulating layer 12.

The photoelectric conversion member 40A includes electrodes, which are accessible within the opening 12x. Similarly, the photoelectric conversion member 40B includes electrodes, which are accessible within the opening 12y. The photoelectric conversion members 40A and 40B convert between optical signals and electrical signals. The photoelectric conversion member 40A and the photoelectric conversion member 40B may have the same or different technical specifications. The photoelectric conversion member 40A and the photoelectric conversion member 40B are representative examples of the first photoelectric conversion members of the present invention. The number of first photoelectric conversion members may be one or three or more.

The photoelectric conversion members 40A and 40B are each configured to convert an input optical signal into an electrical signal for output, and to convert an input electrical signal into an optical signal for output. The photoelectric conversion members 40A and 40B each include, for example, a light receiving device that converts an optical signal into an electrical signal, a light emitting device that converts an electrical signal into an optical signal, and a control circuit that controls the conversion between optical signals and electrical signals. The light receiving device is, for example, a photodiode. The light emitting device is, for example, a laser diode or a light emitting diode.

As an alternative configuration, the photoelectric conversion members 40A and 40B may each include a light receiving device that converts an optical signal into an electrical signal, but may not include a light emitting device that converts an electrical signal into an optical signal. Alternatively, the photoelectric conversion members 40A and 40B may each include a light emitting device that converts an electrical signal into an optical signal, but may not include a light receiving device that converts an optical signal into an electrical signal. In either case, the photoelectric conversion members 40A and 40B may include a control circuit.

The insulating layer 13 is disposed in the openings 12x and 12y on the first surface 10a of the core layer 10 and covers the photoelectric conversion members 40A and 40B. The upper surface of the insulating layer 13 may be flush with the upper surface of the insulating layer 12, for example. The insulating layer 13 may alternatively extend upward from the openings 12x and 12y to cover the upper surface of the insulating layer 12 and be sandwiched between the insulating layer 12 and the insulating layer 14. The material of the insulating layer 13 may be substantially the same as that of the insulating layer 12, for example. The insulating layer 13 may alternatively be formed of a material different from that of the insulating layer 12. For example, the insulating layer 13 may be made of a resin having better embeddability than that of the insulating layer 12. The insulating layer 13 is a representative example of the first insulating layer of the present invention.

The insulating layer 14 is formed on the upper surfaces of the insulating layers 12 and 13. The material of the insulating layer 14 is substantially the same as that of the insulating layer 12, for example. The insulating layer 14 may contain a filler such as silica (SiO₂). The insulating layer 14 includes via holes 14x. The via holes 14x penetrate the insulating layers 13 and 14 such that at least portions of the electrodes of the photoelectric conversion members and 40A and 40B are accessible therethrough. Each via hole 14x may be, for example, an inverted truncated conical recess in which the diameter of the opening toward the insulating layer 16 is larger than the diameter of the bottom surface of the recess formed by the upper surface of a corresponding electrode of the photoelectric conversion members 40A and 40B.

The interconnect layer 15 fills the via holes 14x to be electrically connected to the electrodes of the photoelectric conversion members 40A and 40B, and extends from the inside of the via holes 14x to the upper surface of the insulating layer 14. Specifically, the interconnect layer 15 includes via interconnects filling the via holes 14x and an interconnect pattern formed on the upper surface of the insulating layer 14. The interconnect pattern of the interconnect layer 15 is electrically connected to the electrodes of the photoelectric conversion members 40A and 40B through the via interconnects. The material of the interconnect layer 15 and the thickness of the interconnect pattern are substantially the same as, for example, those of the interconnect layer 11. A via hole may be formed through the insulating layers 12 and 14, so that the interconnect layer 15 and the interconnect layer 11 may be electrically connected through the via hole. The interconnect layer 15 is a representative example of the first interconnect layer of the present invention.

The insulating layer 16 is formed on the upper surface of the insulating layer 14 so as to cover the interconnect layer 15. The material of the insulating layer 16 is substantially the same as that of the insulating layer 12, for example. The insulating layer 16 may contain a filler such as silica (SiO₂). The insulating layer 16 includes via holes 16x. The via holes 16x penetrate the insulating layer 16 so that the upper surface of the interconnect layer 15 is accessible therethrough. The via holes 16x may be, for example, an inverted truncated conical recess in which the diameter of the opening toward the solder resist layer 18 is larger than the diameter of the bottom surface of the recess formed by the upper surface of the interconnect layer 15.

The interconnect layer 17 fills the via holes 16x to be electrically connected to the interconnect layer 15, and extends from the via holes 16x to the upper surface of the insulating layer 16. Specifically, the interconnect layer 17 includes via interconnects filling the via holes 16x and an interconnect pattern formed on the upper surface of the insulating layer 16. The interconnect pattern of the interconnect layer 17 is electrically connected to the interconnect layer 15 through the via interconnects. The material of the interconnect layer 17 and the thickness of the interconnect pattern are substantially the same as, for example, those of the interconnect layer 11.

The solder resist layer 18 is a protective insulating layer situated outermost on the first side of the interconnect substrate 1, and is formed on the upper surface of the insulating layer 16 to cover the interconnect layer 17. The solder resist layer 18 includes openings 18x, so that portions of the upper surface of the interconnect layer 17 are exposed within the openings 18x. The planar shape of each of the openings 18x is, for example, circular. The interconnect layer 17 exposed in each of the openings 18x may be used as a pad for electrical connection to a semiconductor chip or the like. The material of the solder resist layer 18 may be, for example, a photosensitive insulating resin mainly composed of a phenolic-based resin, a polyimide-based resin, or the like. The solder resist layer 18 may contain a filler such as silica (SiO₂). The thickness of the solder resist layer 18 may be, for example, about 25 to 40 μm.

A surface treatment layer may be formed on the upper surface of the interconnect layer 17 exposed in the openings 18x. Examples of the surface treatment layer include an Au layer, an Ni/Au layer (i.e., a metal layer made by laminating an Ni layer and an Au layer in this order), a Ni/Pd/Au layer (i.e., a metal layer made by laminating an Ni layer, a Pd layer, and an Au layer in this order), and the like. The surface treatment layer may alternatively be formed by applying an anti-oxidation treatment such as an OSP (organic solderability preservative) treatment to the upper surface of the interconnect layer 17 exposed in the openings 18x. The OSP treatment may form an organic film made of an azole compound, an imidazole compound, or the like as the surface treatment layer. Projecting electrodes such as metal posts may be formed on the upper surface of the interconnect layer 17 exposed in the openings 18x.

The interconnect layer 21 is disposed on the second surface 10b of the core layer 10. The interconnect layer 21 is patterned in a predetermined planar shape. The material and thickness of the interconnect layer 21 may be substantially the same as those of the interconnect layer 11, for example. The interconnect layer 21 is a representative example of the fourth interconnect layer of the present invention.

The insulating layer 22 is formed on the second surface 10b of the core layer 10 so as to cover the interconnect layer 21. The material and thickness of the insulating layer 22 may be substantially the same as those of the insulating layer 12, for example. The insulating layer 22 may contain a filler such as silica (SiO₂). The insulating layer 22 includes openings 22x and 22y. The second surface 10b of the core layer 10 is situated at the bottom of the openings 22x and 22y.

A photoelectric conversion member 40C is disposed on the second surface 10b of the core layer 10 situated within the opening 22x via a translucent optical adhesive 30. A photoelectric conversion member 40D is disposed on the second surface 10b of the core layer 10 situated within the opening 22y via a translucent optical adhesive 30. The thicknesses of the photoelectric conversion member 40C and the photoelectric conversion member 40D are preferably less than the thickness of the insulating layer 22.

The photoelectric conversion member 40 C includes electrodes, which are accessible within the opening 22x. Similarly, the photoelectric conversion member 40D includes electrodes, which are accessible within the opening 22y. The photoelectric conversion members 40C and 40D convert between optical signals and electrical signals. The photoelectric conversion member 40C and the photoelectric conversion member 40D may have the same or different technical specifications. The photoelectric conversion member 40C and the photoelectric conversion member 40D are representative examples of the second photoelectric conversion members of the present invention. The number of second photoelectric conversion members may be one or three or more.

The photoelectric conversion members 40C and 40D is each configured to convert an input optical signal into an electrical signal for output, and to convert an input electrical signal into an optical signal for output. The photoelectric conversion members 40C and 40D each include, for example, a light receiving device that converts an optical signal into an electrical signal, a light emitting device that converts an electrical signal into an optical signal, and a control circuit that controls the conversion between optical signals and electrical signals. The light receiving device is, for example, a photodiode. The light emitting device is, for example, a laser diode or a light emitting diode.

As an alternative configuration, the photoelectric conversion members 40C and 40D may each include a light receiving device that converts an optical signal into an electrical signal, but may not include a light emitting device that converts an electrical signal into an optical signal. Alternatively, the photoelectric conversion members 40C and 40D may each include a light emitting device that converts an electrical signal into an optical signal, but may not include a light receiving device that converts an optical signal into an electrical signal. In either case, the photoelectric conversion members 40C and 40D may each include a control circuit.

The photoelectric conversion member 40C is arranged at such a position as to transmit light to and receive light from the photoelectric conversion member 40A through the core layer 10. The photoelectric conversion member 40C may be arranged at such a position as to overlap the photoelectric conversion member 40A in plan view, for example. Similarly, the photoelectric conversion member 40D is arranged at such a position as to transmit light to and receive light from the photoelectric conversion member 40B through the core layer 10. The photoelectric conversion member 40D may be arranged at such a position as to overlap the photoelectric conversion member 40B in plan view, for example.

When each of the photoelectric conversion members 40A and 40B is provided with a light emitting device but without a light receiving device, each of the photoelectric conversion members 40C and 40D may be provided with a light receiving device but without a light emitting device. Alternatively, when each of the photoelectric conversion members 40A and 40B is provided with a light receiving device but without a light emitting device, each of the photoelectric conversion members 40C and 40D may be provided with a light emitting device but without a light receiving device.

The insulating layer 23 is arranged in the openings 22x and 22y on the second surface 10b of the core layer 10 and covers the photoelectric conversion members 40C and 40D. The lower surface of the insulating layer 23 may be flush with the lower surface of the insulating layer 22, for example. The insulating layer 23 may alternatively extend downward from the openings 22x and 22y to cover the lower surface of the insulating layer 22, and may be sandwiched between the insulating layer 22 and the insulating layer 24. The material of the insulating layer 23 may be substantially the same as that of the insulating layer 22, for example. The insulating layer 23 may alternatively be formed of a material different from that of the insulating layer 22. For example, the insulating layer 23 may be made of a resin having better embeddability than that of the insulating layer 22. The insulating layer 23 is a representative example of the second insulating layer of the present invention.

The insulating layer 24 is formed on the lower surfaces of the insulating layers 22 and 23. The material of the insulating layer 24 is substantially the same as that of the insulating layer 22, for example. The insulating layer 24 may contain a filler such as silica (SiO₂). The insulating layer 24 includes via holes 24x. The via holes 24x penetrate the insulating layers 23 and 24 such that at least portions of the electrodes of the photoelectric conversion members 40C and 40D are accessible therethrough. The via holes 24x may each be, for example, a truncated conical recess in which the diameter of the opening toward the insulating layer 26 is larger than the diameter of the end surface of the recess formed by the lower surface of a corresponding electrode of the photoelectric conversion members 40C and 40D.

The interconnect layer 25 fills the via holes 24x to be electrically connected to the electrodes of the photoelectric conversion members 40C and 40D, and extends from the inside of the via holes 24x to the lower surface of the insulating layer 24. Specifically, the interconnect layer 25 includes via interconnects filling the via holes 24x and an interconnect pattern formed on the lower surface of the insulating layer 24. The interconnect pattern of the interconnect layer 25 is electrically connected to the electrodes of the photoelectric conversion members 40C and 40D through the via interconnects. The material of the interconnect layer 25 and the the interconnect pattern are thickness of substantially the same as, for example, those of the interconnect layer 11. Via holes may be formed through the insulating layers 22 and 24 so that the interconnect layer 25 and the interconnect layer 21 may be electrically connected through these via holes. The interconnect layer 25 is a representative example of the second interconnect layer of the present invention.

The insulating layer 26 is formed on the lower surface of the insulating layer 24 so as to cover the interconnect layer 25. The material of the insulating layer 26 is substantially the same as that of the insulating for layer 12, example. The insulating layer 26 may contain a filler such as silica (SiO₂). The insulating layer 26 includes via holes 26x. The via holes 26x penetrate the insulating layer 26 so that the lower surface of the interconnect layer 25 is accessible therethrough. The via holes 26x may each be, for example, a truncated conical recess in which the diameter of the opening toward the solder resist layer 28 is larger than the diameter of the end surface of the recess formed by the lower surface of the interconnect layer 25.

The interconnect layer 27 fills the via holes 26x to be electrically connected to the interconnect layer 25, and extends from the inside of the via holes 26x to the lower surface of the insulating layer 26. Specifically, the interconnect layer 27 includes via interconnects filling the via holes 26x and an interconnect pattern formed on the lower surface of the insulating layer 26. The interconnect pattern of the interconnect layer 27 is electrically connected to the interconnect layer 25 through the via interconnects. The material of the interconnect layer 27 and the thickness of the interconnect pattern are, for example, substantially the same as those of the interconnect layer 11.

The solder resist layer 28 is a protective insulating layer situated outermost on the second side of the interconnect substrate 1, and is formed on the lower surface of the insulating layer 26 so as to cover the interconnect layer 27. The solder resist layer 28 includes openings 28x, and portions of the lower surface of the interconnect layer 27 are exposed within the openings 28x. The planar shape of each of the openings 28x is, for example, circular. The interconnect layer 27 exposed in the openings 28x may be used as pads for electrical connection to another interconnect substrate. The material of the solder resist layer 28 may be, for example, a photosensitive insulating resin mainly composed of a phenolic-based resin, a polyimide-based resin, or the like. The solder resist layer 28 may contain a filler such as silica (SiO₂). The thickness of the solder resist layer 28 is, for example, about 25 to 40 μm.

A surface treatment layer may be formed on the lower surface of the interconnect layer 27 exposed in the openings 28x. Examples of the surface treatment layer are as described above. Projecting electrodes such as metal posts may be formed on the lower surface of the interconnect layer 27 exposed in the openings 28x.

In the manner as described above, the interconnect substrate 1 includes the translucent core layer 10, the photoelectric conversion members 40A and 40B disposed on the first surface 10a of the core layer 10, and the interconnect layer 15 electrically connected to the photoelectric conversion members 40A and 40B. The interconnect substrate 1 also includes the photoelectric conversion members 40C and 40D disposed on the second surface 10b of the core layer 10, and the interconnect layer 25 electrically connected to the photoelectric conversion members 40C and 40D. Positional alignment is ensured such that optical signals are effectively exchanged via the core layer 10 between the photoelectric conversion member 40A and the photoelectric conversion member 40C as well as between the photoelectric conversion member 40B and the photoelectric conversion member 40D.

This arrangement enables the interconnect layer 15 and the interconnect layer 25 to be connected by optical signals transmitted through the core layer 10. For example, the electrical signal input from the interconnect layer 15 to the photoelectric conversion member 40A is converted into an optical signal by the photoelectric conversion member 40A for transmission to the photoelectric conversion member 40C via the core layer 10. The photoelectric conversion member 40C converts the received optical signal into an electrical signal for transmission to the interconnect layer 25. Optical signal transmission and reception in the opposite direction is also enabled.

In other words, the interconnect substrate 1 effectively transmit and receive signals between the first surface 10a and the second surface 10b without providing the through-interconnects that penetrate the core layer 10. This arrangement enables the reduction in number or elimination of through-interconnects that would be conventionally required in the core layer 10 in large numbers. This arrangement thus effectively suppresses the deterioration of the strength of the core layer 10 and to reduce the risk of breakage of the core layer 10.

Further, when the core layer 10 is made of glass, hydrofluoric acid, which is highly dangerous, is used to form through-holes in the core layer 10. The reduction in number or elimination of through-holes effectively decreases the amount of hydrofluoric acid used, which improves safety. In addition, the cost of forming through holes can be reduced.

### Method of Making Interconnect Substrate

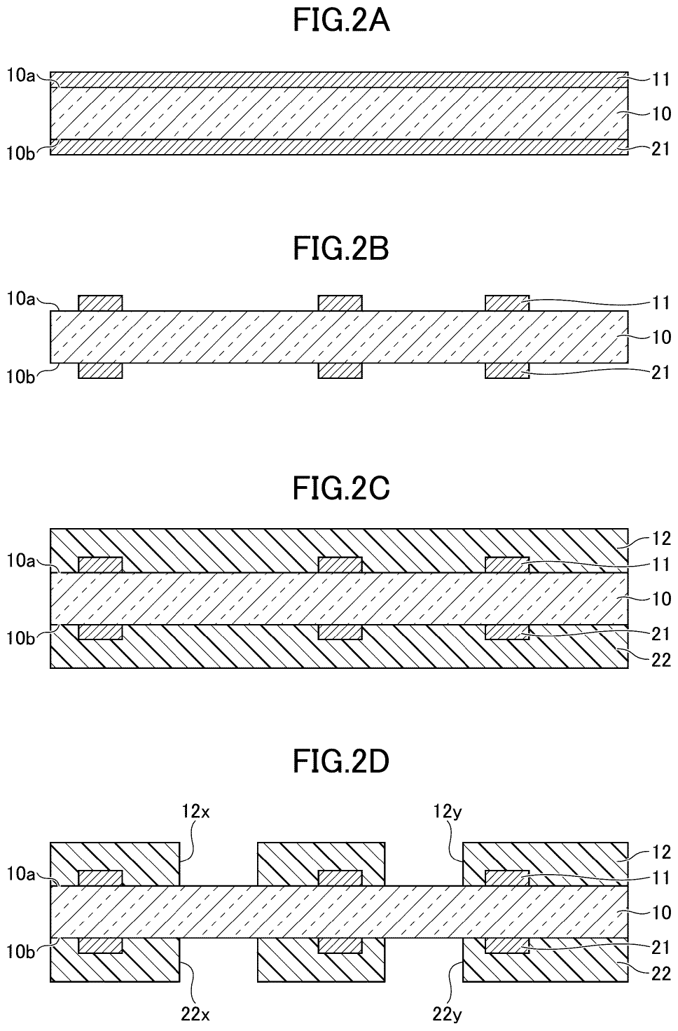

FIGS. 2A through 2D to FIGS. 4A through 4C are drawings an illustrating example of the manufacturing process of the interconnect substrate according to the first embodiment. Although the following description is directed to an example of a process of fabricating a single interconnect substrate, a plurality of portions to become respective interconnect substrates may be collectively fabricated, followed by singulation into individual interconnect substrates.

First, in the step illustrated in FIG. 2A, the translucent core layer 10 is prepared. Then, an unpatterned interconnect layer 11 is formed on the first surface 10a of the core layer 10, and an unpatterned interconnect layer 21 is formed on the second surface 10b of the core layer 10. The interconnect layers 11 and 21 may be formed by, for example, sputtering, electroless plating, or the like. In order to improve the adhesion between the interconnect layers 11 and 21 and the core layer 10, a layer of metal or metal oxide film different from the material constituting the interconnect layers 11 and 21 may be formed on the core layer 10.

Next, in the step illustrated in FIG. 2B, the interconnect layers 11 and 21 are patterned into predetermined planar shapes. For the patterning of the interconnect layers 11 and 21, a well-known subtractive method or the like may be used.

In the step illustrated in FIG. 2C, a semi-cured epoxy-based resin film or the like is laminated on the first surface 10a of the core layer 10 so as to cover the interconnect layer 11 and cured to form the insulating layer 12. In addition, a semi-cured epoxy-based resin film or the like is laminated on the second surface 10b of the core layer 10 so as to cover the interconnect layer 21 and cured to form the insulating layer 22. Alternatively, instead of laminating an epoxy-based resin film or the like, an epoxy-based resin in liquid or paste form or the like may be applied and cured to form each of the insulating layers 12 and 22. The insulating layers 12 and 22 are preferably thicker than the photoelectric conversion members to be disposed after this step.

In the step illustrated in FIG. 2D, the openings 12x and 12y which penetrate the insulating layer 12 and expose the first surface 10a of the core layer 10 are formed in the insulating layer 12. Openings 22x and 22y which penetrate the insulating layer 22 and expose the second surface 10b of the core layer 10 are formed in the insulating layer 22. The openings 12x and 22x are formed at positions that are opposite each other across the core layer 10. The openings 12y and 22y are formed at positions that are opposite each other across the core layer 10. Each of the openings may be formed by a laser processing method using, for example, a CO₂ laser or the like. The inner surface of each of the openings forms a cavity for housing a photoelectric conversion member.

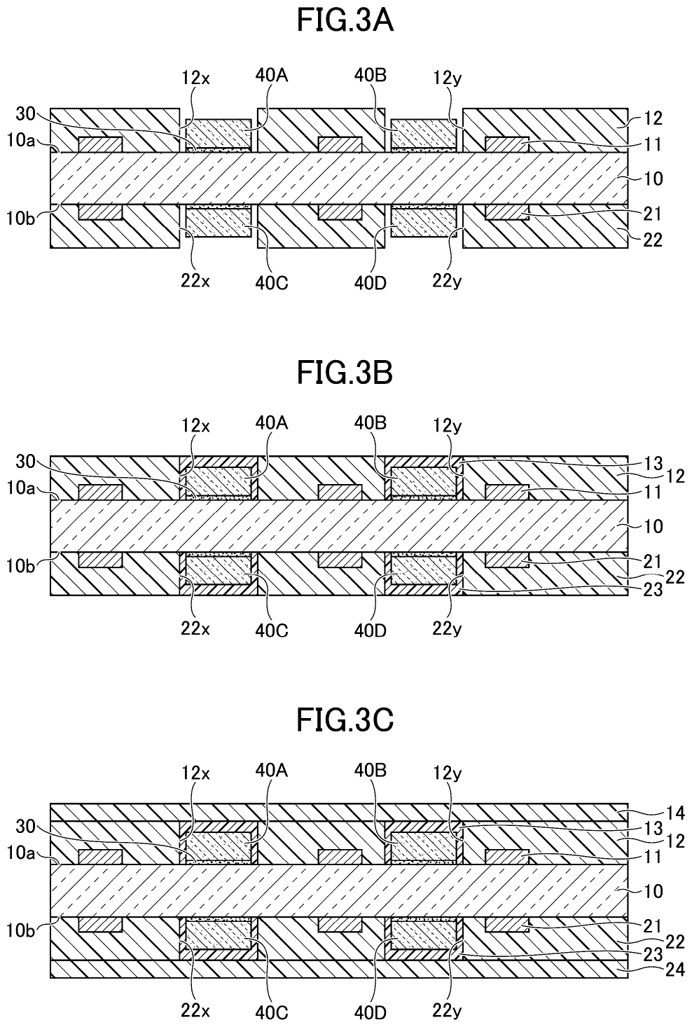

In the step illustrated in FIG. 3A, the photoelectric conversion members 40A, 40B, 40C, and 40D having electrodes are prepared. Then, the photoelectric conversion members 40A and 40B are arranged on the first surface 10a of the core layer 10, and the photoelectric conversion members 40C and 40D are arranged on the second surface 10b of the core layer 10.

Specifically, the photoelectric conversion member 40A is arranged on the first surface 10a of the core layer 10 exposed inside the opening 12x via the translucent optical adhesive 30 such that its electrodes are exposed inside the opening 12x. On the first surface 10a of the core layer 10 exposed inside the opening 12y, the photoelectric conversion member 40B is arranged via the translucent optical adhesive 30 such that its electrodes are exposed inside the opening 12y.

Similarly, on the second surface 10b of the core layer 10 exposed inside the opening 22x, the photoelectric conversion member 40C is arranged via the translucent optical adhesive 30 such that its electrodes are exposed inside the opening 22x. On the second surface 10b of the core layer 10 exposed inside the opening 22y, the photoelectric conversion member 40D is arranged via the translucent optical adhesive 30 such that its electrodes are exposed inside the opening 22y.

The photoelectric conversion member 40C is arranged at such a position as to transmit light to and receive light from the photoelectric conversion member 40A through the core layer 10. Similarly, the photoelectric conversion member 40D is arranged at such a position as to transmit light to and receive light from the photoelectric conversion member 40B through the core layer 10.

In the step illustrated in FIG. 3B, the insulating layer 13 is formed to fill the opening 12x to cover the photoelectric conversion member 40A and fill the opening 12y to cover the photoelectric conversion member 40B. In addition, the insulating layer 23 is formed to fill the opening 22x to cover the photoelectric conversion member 40C and fill the opening 22y to cover the photoelectric conversion member 40D. The insulating layers 13 and 23 are each formed, for example, by laminating a semi-cured epoxy-based resin film or the like so as to cover each photoelectric conversion member, and then curing the film. Alternatively, instead of laminating an epoxy-based resin film or the like, an epoxy-based resin in liquid or paste form or the like may be applied and cured to form each of the insulating layers 13 and 23.

In the step illustrated in FIG. 3C, a semi-cured epoxy-based resin film or the like is laminated on the upper surfaces of the insulating layers 12 and 13 and cured to form the insulating layer 14. Further, a semi-cured epoxy-based resin film or the like is laminated on the lower surfaces of the insulating layers 22 and 23 and cured to form the insulating layer 24. Alternatively, instead of laminating an epoxy-based resin film or the like, an epoxy-based resin or the like in liquid or paste form is applied and cured to form each of the insulating layers 14 and 24.

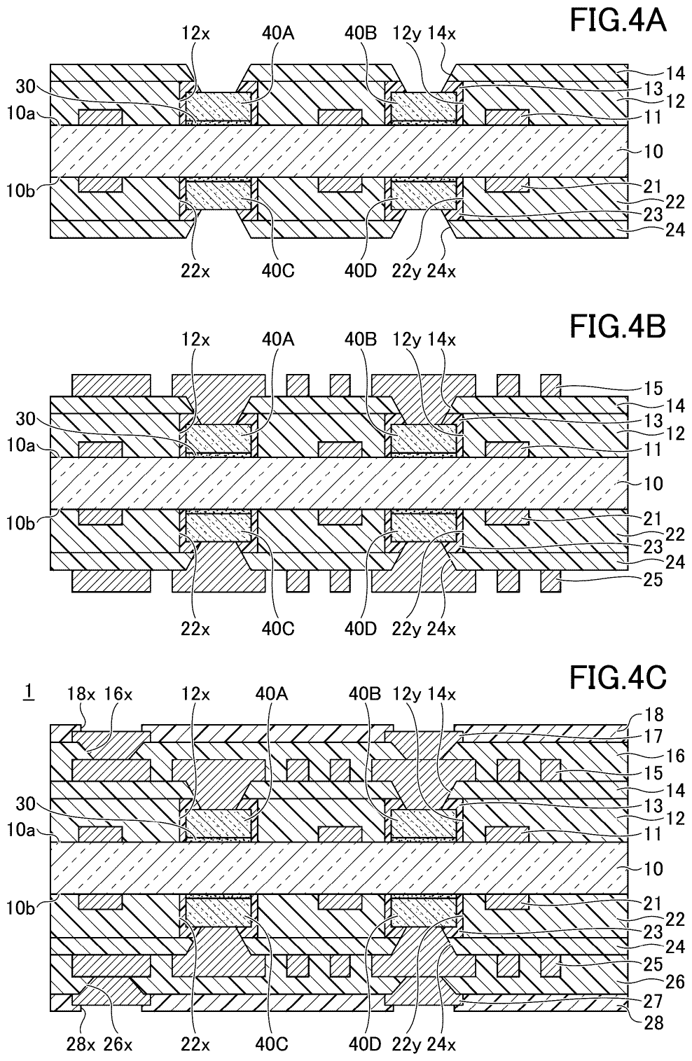

In the step illustrated in FIG. 4A, the via holes 14x penetrating the insulating layers 13 and 14 and exposing the electrodes of the photoelectric conversion members 40A and 40B are formed in the insulating layers 13 and 14. In addition, the via holes 24x penetrating the insulating layers 23 and 24 and exposing the electrodes of the photoelectric conversion members 40C and 40D are formed in the insulating layers 23 and 24. The via holes 14x and 24x may be formed by a laser processing method using, for example, a CO₂ laser. After the via holes 14x and 24x are formed, desmear treatment is preferably performed to remove resin residues adhering to the surfaces of the electrodes exposed at the bottoms of the via holes 14x and 24x.

In the step illustrated in FIG. 4B, the interconnect layer 15 electrically connected to the photoelectric conversion members 40A and 40B is formed, and, also, the interconnect layer 25 electrically connected to the photoelectric conversion members 40C and 40D are formed. The interconnect layer 15 includes the via interconnects filling the via holes 14x and the interconnect pattern formed on the upper surface of the insulating layer 14. The interconnect layer 25 includes the via interconnects filling the via holes 24x and the interconnect pattern formed on the lower surface of the insulating layer 24.

The interconnect layers 15 and 25 may be formed using, for example, a semi-additive method. Specifically, for example, a seed layer is formed by electroless plating of copper on the upper surface of the insulating layer 14, the inner surface of the via holes 14x, and the upper surfaces of electrodes exposed in the via holes 14x. On the seed layer, a plating resist pattern having openings matching the shape of the interconnect pattern of the interconnect layer 15 is formed, and an electrolytic plating layer is deposited on the seed layer exposed in the openings of the plating resist pattern by electrolytic plating of copper or the like using the seed layer as a power supply path. Thereafter, the plating resist pattern is removed, followed by etching using the electrolytic plating layer as a mask to remove the seed layer exposed from the electrolytic plating layer. These steps effectively fabricate the interconnect layer 15 having the via interconnects and the interconnect pattern. The interconnect layer 25 may be formed in substantially the same manner.

In the step illustrated in FIG. 4C, the insulating layer 16 and the interconnect layer 17 are formed on the interconnect layer 15 in substantially the same manner as in FIGS. 2C, 4A, and 4B. The insulating layer 26 and the interconnect layer 27 are also formed on the interconnect layer 25. Then, the solder resist layer 18 is formed on the upper surface of the insulating layer 16 so as to cover the interconnect layer 17. The solder resist layer 28 is formed on the lower surface of the insulating layer 26 so as to cover the interconnect layer 27. The solder resist layer 18 may be formed by applying, for example, a photosensitive epoxy-based insulating resin or acrylic-based insulating resin in liquid or paste form to the upper surface of the insulating layer 16 so as to cover the interconnect layer 17 by screen printing, roll coating, spin coating, or the like. Alternatively, a photosensitive epoxy-based or acrylic-based insulating resin film may be laminated on the upper surface of the insulating layer 16 so as to cover the interconnect layer 17. The method of forming the solder resist layer 28 is substantially the same as that of the solder resist layer 18.

Subsequently, by exposing and developing the solder resist layers 18 and 28, the openings 18x exposing portions of the upper surface of the interconnect layer 17 are formed in the solder resist layer 18, and the openings 28x exposing portions of the lower surface of the interconnect layer 27 are formed in the solder resist layer 28. The planar shapes of the openings 18x and 28x may each be, for example, circular. The diameters of the openings 18x and 28x may be designed as appropriate according to the connected object (e.g., semiconductor chip, motherboard, etc.).

In this step, the aforementioned metal layer may be formed on the upper surface of the interconnect layer 17 exposed at the bottoms of the openings 18x and on the lower surface of the interconnect layer 27 exposed at the ends of the openings 28x by electroless plating, for example. Alternatively, oxidation prevention treatment such as OSP treatment may be performed instead of forming the metal layer. These steps fabricate the interconnect substrate 1 in its final form.

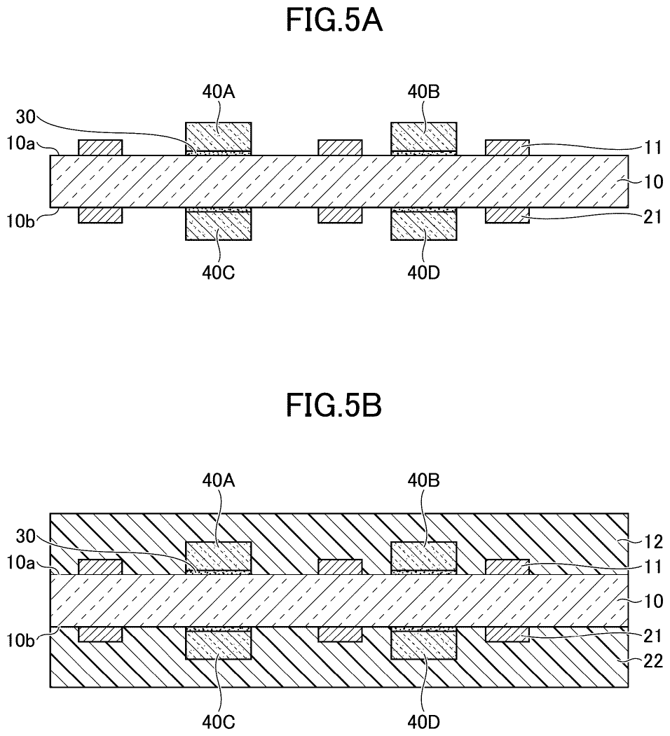

The manufacturing process of the interconnect substrate 1 may be modified as follows. First, the same steps as in FIGS. 2A and 2B are performed. Then, in the step illustrated in FIG. 5A, the photoelectric conversion members 40A, 40B, 40C, and 40D having electrodes are prepared. The photoelectric conversion members 40A and 40B are arranged at predetermined positions on the first surface 10a of the core layer 10 via the translucent optical adhesive 30 such that their electrodes face upward. Also, the photoelectric conversion members 40C and 40D are arranged at predetermined positions on the second surface 10b of the core layer 10 via the translucent optical adhesive 30 such that their electrodes face downward. The photoelectric conversion member 40C is arranged at such a position as to transmit light to and receive light from the photoelectric conversion member 40A through the core layer 10. Similarly, the photoelectric conversion member 40D is arranged at such a position as to light to and receive light from the transmit photoelectric conversion member 40B through the core layer 10.

In the step illustrated in FIG. 5B, the layer 12 covering the photoelectric insulating conversion members 40A and 40B is formed. In addition, the insulating layer 22 covering the photoelectric conversion members 40C and 40D is formed. The method of forming the insulating layers 12 and 22 may be substantially the same as the step illustrated in FIG. 2C. The insulating layers 12 and 22 are formed so as to cover the entire photoelectric conversion members including the electrodes.

Thereafter, substantially the same steps as in FIGS. 4A to 4C are performed, which results in the final form of the interconnect substrate 1. In this manufacturing the step of process, forming the insulating layers 13 and 14 and the insulating layers 23 and 24 is unnecessary. In other words, the insulating layer 12 serves the roles of the insulating layers 13 and 14, and the insulating layer 22 serves the roles of the insulating layers 23 and 24.

### Variation of First Embodiment

The variation of the first embodiment is directed to an example of an interconnect substrate including a through interconnect that penetrates the core layer and electrically connects interconnect layers. In connection with the variation of the first embodiment, descriptions of the same components as those of the already described embodiment may be omitted.

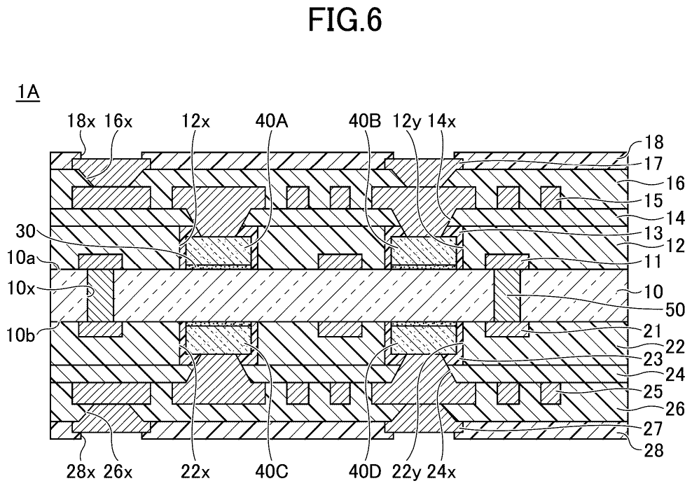

FIG. 6 is a cross-sectional view illustrating an example of an interconnect substrate according to the variation of the first embodiment. An interconnect substrate 1A illustrated in FIG. 6 differs from the interconnect substrate 1 in that through interconnects 50 are added.

The through interconnects 50 are disposed inside through holes 10x penetrating the core layer 10. The interconnect layer 11 and the interconnect layer 21 are electrically connected by the through interconnects 50. The material of the through interconnects 50 may be, for example, copper (Cu) or the like. The planar shape of each of the through interconnects 50 is, for example, circular. When the plane shape of each of the through interconnects 50 is circular, for example, the diameter may be 10 μm or more and 100 μm or less.

The through holes 10x may be formed by, for example, laser processing, etching processing, or both. When the core layer 10 is glass and the through holes 10x are formed by etching, hydrofluoric acid may be used, for example. The through interconnects 50 may be formed by a semi-additive method, for example. The through interconnects 50 may be formed seamlessly with the interconnect layer 11 and the interconnect layer 21.

In this manner, signal transmission and reception through the core layer 10 may be performed by both optical signals and electrical signals. For example, the power supply interconnects and the GND interconnects may be connected by electrical signals through the through interconnects 50, and signal interconnects may be connected by optical signals.

According to at least one embodiment, an interconnect substrate capable of suppressing a decrease in the strength of the core layer is effectively provided.

The present disclosures non-exclusively contain the subject matter set out in the following clause.

[Clause] A method of making an interconnect substrate, comprising:

disposing a first photoelectric conversion member on a first surface of a translucent core layer and disposing a second photoelectric conversion member on a second surface of the translucent core layer that is opposite the first surface;

forming both a first interconnect layer electrically connected to the first photoelectric conversion member and a second interconnect layer electrically connected to the second photoelectric conversion member; and

wherein the first photoelectric conversion member and the second photoelectric conversion member are disposed at such positions as to exchange optical signals with each other through the translucent core layer.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. An interconnect substrate comprising:
a core layer that is translucent;
a first photoelectric conversion member disposed on a first surface of the core layer;
a first interconnect layer electrically connected to the first photoelectric conversion member;
a second photoelectric conversion member disposed on a second surface of the core layer that is opposite the first surface; and
a second interconnect layer electrically connected to the second photoelectric conversion member,
wherein the first photoelectric conversion member and the second photoelectric conversion member are arranged at such positions as to exchange optical signals with each other through the core layer.

2. The interconnect substrate as claimed in claim 1, wherein the first photoelectric conversion member and the second photoelectric conversion member each include a light receiving device configured to convert an optical signal into an electrical signal, a light emitting device configured to convert an electrical signal into an optical signal, and a control circuit configured to control conversion between optical signals and electrical signals.

3. The interconnect substrate as claimed in claim 1, wherein one of the first photoelectric conversion member and the second photoelectric conversion member includes a light receiving device configured to convert an optical signal into an electrical signal but does not include a light emitting device configured to convert an electrical signal into an optical signal, and
another one of the first photoelectric conversion member and the second photoelectric conversion member includes a light emitting device configured to convert an electrical signal into an optical signal but does not include a light receiving device configured to convert an optical signal into an electrical signal.

4. The interconnect substrate as claimed in claim 1, further comprising:
a third interconnect layer disposed on the first surface of the core layer;
a fourth interconnect layer disposed on the second surface of the core layer; and
a through-interconnect penetrating the core layer to electrically connect the third interconnect layer and the fourth interconnect layer.

5. The interconnect substrate as claimed in claim 1, wherein the core layer is made of glass.

6. The interconnect substrate as claimed in claim 1, wherein the first photoelectric conversion member is disposed on the first surface of the core layer via a translucent optical adhesive, and the second photoelectric conversion member is disposed on the second surface of the core layer via a translucent optical adhesive.

7. The interconnect substrate as claimed in claim 1, further comprising:
a first insulating layer disposed on the first surface of the core layer and covering the first photoelectric conversion member;
a second insulating layer disposed on the second surface of the core layer and covering the second photoelectric conversion member.

8. The interconnect substrate as claimed in claim 7, further comprising:
a third insulating layer disposed on the first surface of the core layer and having a first opening in which the first photoelectric conversion member is disposed, the first insulating layer filling the first opening; and
a fourth insulating layer disposed on the second surface of the core layer and having a second opening in which the second photoelectric conversion member is disposed, the second insulating layer filling the second opening.

9. The interconnect substrate as claimed in claim 1, wherein the first photoelectric conversion member and the second photoelectric conversion member are aligned with each other in plan view and arranged opposite each other across an area of the core layer, and the area of the core layer is free of a through-hole.
